(19) United States
(12) Patent Application Publication
(10) Pub. No.: US 2003/0087166 A1
(43) Pub. Date: May 8, 2003

(54) Reticle and a method for manufacturing a semiconductor device using the same

(75) Inventors: Sang-Tae Choi, Seoul (KR); Moon-Hwoi Kim, Seoul (KR); Kwang-Chul Kim, Kyunggi-Do (KR)

Correspondence Address: MARSHALL, GERSTEIN & BORUN, 6300 SEARS TOWER, 233 SOUTH WACKER, CHICAGO, IL, 60606-6357, US

(73) Assignee: HYNIX SEMICONDUCTOR INC., Ichon-Shi (KR)

(21) Appl. No.: 10/289,766

(22) Filed: Nov. 7, 2002

(30) Foreign Application Priority Data
Nov. 8, 2001 (KR) 2001-69568

(51) Int. Cl. G03F 9/00; G03C 5/00

(52) U.S. Cl. 430/5; 430/311; 430/330

(57) ABSTRACT

Disclosed is a method for manufacturing a semiconductor device, wherein a reticle that can expose only a portion where the pattern is changed on an edge area of a wafer is manufactured, and then a double exposure process is performed by using the reticle, whereby all of the photoresist on the part where the pattern is changed is removed. There are advantages that the yield of the semiconductor device is enhanced, and the electrical properties thereof are improved.

### TECHNICAL FIELD

A method for manufacturing a semiconductor device, and more particularly, a reticle and a method for manufacturing a semiconductor device using the reticle are disclosed, in which the reticle exposes only a portion where the pattern is changed among the edge area of a wafer is manufactured, and then a double exposure process is performed using the reticle, whereby all of the photoresist on the portion where the pattern is changed is removed.

### DESCRIPTION OF THE RELATED ART

Generally, a photo etching process for forming a photoresist pattern in a manufacturing process of a semiconductor device comprises a coating process for coating a photoresist layer on a silicon wafer, an exposure process for selectively exposing the photoresist on the wafer by using a reticle (mask), and a development process for forming a minute circuit pattern by developing the exposed photoresist layer.

In a recent exposure process, an edge area exposure process is also performed to remove the photoresist layer coated on the edge area of the wafer. Then, the photoresist remaining on the edge area will not act as impurities in the following processes.

In an exposure process using a reticle according to a conventional method for manufacturing the semiconductor device, the exposure process is performed not on the basis of a single die but with as many dies as possible, which are arranged in a reticle and then exposed simultaneously, thereby increasing exposure speed.

However, according to the conventional technology, as shown in FIG. 1, the edge area that does not have to be exposed is also exposed, and accordingly the differences in height may occur. The differences in height cause a defocusing and therefore a deformity of the circuit pattern.

Furthermore, the deformed pattern may function as a defect in the following processes, which causes the defect of the device as if there were flowing of liquid as shown in FIG. 2, and therefore, the characteristic of the semiconductor device is deteriorated.

### SUMMARY OF THE DISCLOSURE

A method for manufacturing a semiconductor device and a reticle used in the method are disclosed, in which a reticle that can expose only a portion of a pattern that is changed along an edge area of a wafer coated with a multiple photoresist layer is manufactured, and then a double exposure process is performed using the reticle, whereby the final photoresist pattern where the multiple photoresist layers remain only on the portion where the pattern is changed is formed, and accordingly, the etched pattern is not formed on that portion where the pattern is changed.

In one disclosed aspect, a reticle is disclosed which has a first opening for forming a pattern of a certain size, and a circumferential area surrounding the first opening, the reticle further has a second opening.

In another disclosed aspect, a method for manufacturing a semiconductor device is disclosed which comprises: coating a negative photoresist on a wafer; forming a negative photoresist pattern by performing an exposure process and a development process of the negative photoresist on an edge area of the wafer, by using the reticle; coating a positive photoresist on a resultant area; forming a positive photoresist pattern by performing an exposure process and a development process of the positive photoresist on an area formed with the pattern, by using the reticle; and forming a circuit pattern by etching the positive photoresist with a mask.

As a result, when the photoresist pattern for etching the wafer is formed, the negative photoresist pattern remains on the edge of the wafer and then the positive photoresist pattern is formed on the entire area of the wafer and then is etched, whereby an unnecessary pattern from the etching process is not formed on the edge area of the wafer

### BRIEF DESCRIPTION OF THE DRAWINGS

Other objects and aspects of this disclosure will become apparent from the following description of a preferred embodiment with reference to the accompanying drawings, wherein:

FIGS. 1 and 2 illustrate a problem resulting from manufacturing semiconductor devices by conventional methods;

FIGS. 3 and 4 illustrate a reticle according to a disclosed embodiment and a wafer map of a wafer that has undergone an exposure process with the disclosed reticle; and

FIGS. 5A through 5F are sectional views consecutively illustrating a disclosed method for manufacturing the semiconductor device.

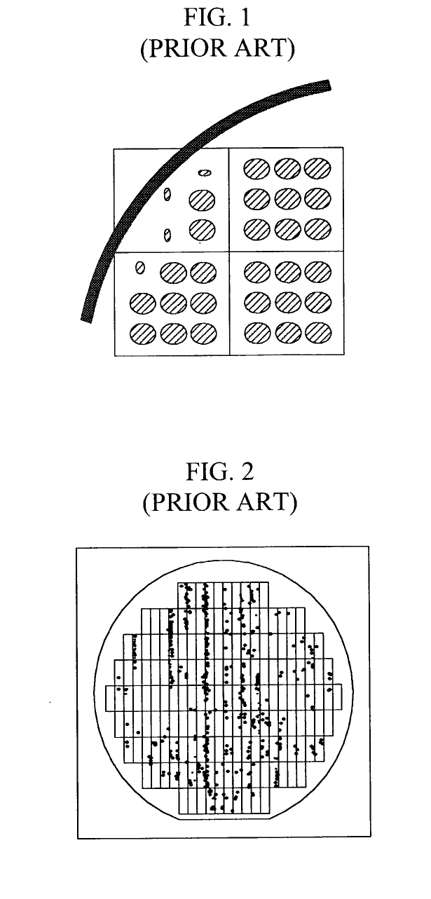

### DETAILED DESCRIPTION OF THE PRESENTLY PREFERRED EMBODIMENTS

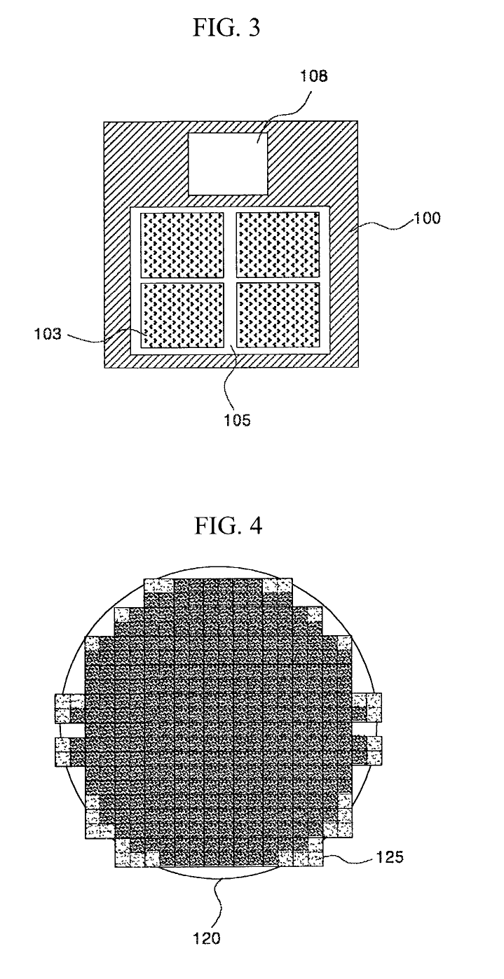

FIGS. 3 and 4 are views illustrating a reticle according to a disclosed embodiment and a wafer map of a wafer that has undergone an exposure process with the reticle.

As shown in FIG. 3, the reticle 100 according to this disclosure has a first opening 103 for forming a pattern of a certain size, and a circumferential area 105 surrounding the first opening 103, and further has a second opening 108.

The second opening 108 is formed to expose only the portion of the wafer where the pattern is changed on the edge area of the wafer. That is, by double exposure of the area where the pattern is changed using the second opening 108, the photoresist is removed or remains thereby preventing further deformity of the pattern.

Then, as shown in FIG. 4, when the exposure process is performed using the reticle 100, the blade process is performed only on the second opening 108 of the reticle 100 to perform the exposure process only on the portion where the pattern is changed on the edge area of the wafer. Then the exposed area 125 appears on the wafer.

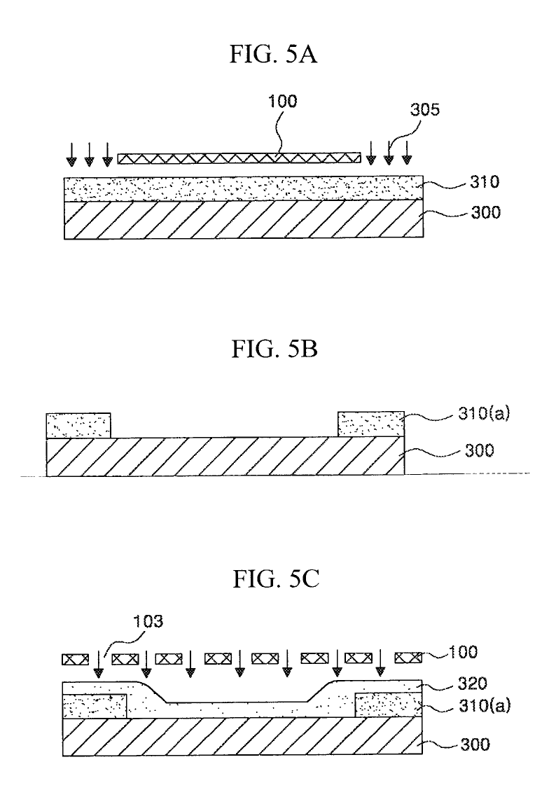

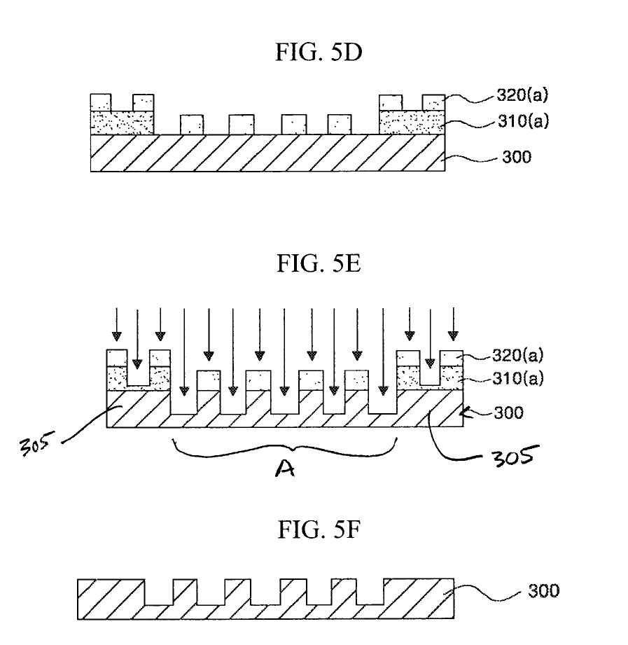

FIGS. 5A through 5F are sectional views consecutively showing the method for manufacturing the semiconductor device according to the preferred embodiment of the present invention.

As shown in FIG. 5A, a negative photoresist 310 is coated on the wafer 300, and then a first exposure process is performed only on the edge area 305 of the wafer by performing a blade process of the second opening (not shown) of the reticle 100.

In such a situation, instead of the negative photoresist, a positive photoresist can be heated to a temperature ranging from about 200 to about 250° C. Preferably, the positive photoresist material should not be soluble in a solvent used in the process.

Then, as shown in FIG. 5B, as the wafer 300 that has undergone the first exposure process is developed, according to the characteristics of the negative photoresist, the negative photoresist on the edge area 305 of the wafer that has been exposed remains on the wafer 300 to form a negative photoresist pattern 310a and the other parts are removed.

Next, as shown in FIG. 5C, a positive photoresist 320 is coated on the entire area and the blade process of the first opening 103 is performed, and then the second exposure process is performed using the reticle 100.

Afterwards, as shown in FIG. 5D, as the wafer 300 that has undergone a second exposure process is developed, according to the characteristics of the positive photoresist, the exposed part is removed and the other part remains on the area to form a positive photoresist pattern 320a. In such a situation, on the edge area of the wafer 300, the photoresist pattern 320a is formed on top of the negative photoresist pattern 310a that has been formed already.

After that, as shown in FIG. 5E, as the water etching process is performed by using the positive photoresist pattern 320a as a mask, a pattern is formed on the central area A of the wafer 300 but the pattern is not formed on the edge area 305 of the wafer 300, since etching is prevented by the negative photoresist pattern 310a formed on the edge area 305 of the wafer 300.

Then, as shown in FIG. 5F, the circuit pattern is formed on the wafer 300 by removing the photoresist remaining on the wafer 300.

According to the disclosed method for manufacturing a semiconductor device, by removing the photoresist at the part where the pattern is changed on the wafer to remove the part where the pattern is changed, the etching pattern is not formed during the following etching process, whereby the uniformity of the CD can be improved, and the characteristic and reliability of the semiconductor device is improved.

Although a preferred embodiment has been described, it will be understood by those skilled in the art that this disclosure should not be limited to the described preferred embodiment, but various changes and modifications can be made within the spirit and the scope of this disclosure. Accordingly, the scope of this disclosure is not limited within the described range but by the following claims.

What is claimed is:

1. A reticle comprising:
a first opening for forming a pattern of a certain size;
a circumferential area surrounding the first opening; and
the reticle further comprising a second opening.

2. The reticle of claim 1, wherein the second opening is formed to a desired size by a user.

3. A method for manufacturing a semiconductor device using a reticle of claim 1, the method comprising:
coating a negative photoresist on a wafer;
forming a negative photoresist pattern by performing an exposure process and a development process of the photoresist on an edge area of the wafer by using the reticle;
coating a positive photoresist on a resultant area;
forming a positive photoresist pattern by performing an exposure process and a development process of the positive photoresist on an area formed with the pattern, by using the reticle; and
forming a circuit pattern by etching the positive photoresist with a mask.

4. The method for manufacturing a semiconductor device of claim 3, wherein the negative photoresist is a material which is not soluble in organic solvents.

5. The method for manufacturing a semiconductor device of claim 4, wherein the material is a positive photoresist heated to a temperature ranging from about 200 to about 250° C.
